(19) United States
(12) Patent Application Publication
(10) Pub. No.: US 2026/0290238 A1
(43) Pub. Date: Sep. 24, 2026

(54) Pixel, Display Device and, Driving Method of the Display Device

(71) Applicant: LG Display Co., Ltd., Seoul (KR)

(72) Inventor: Hongseok CHOI, Paju-si (KR)

(21) Appl. No.: 19/425,898

(22) Filed: Dec. 18, 2025

(30) Foreign Application Priority Data
Mar. 19, 2025 (KR) 10-2025-0035009

(51) Int. Cl. G09G 3/3233

(52) U.S. Cl. CPC G09G 3/3233; G09G 2300/0426; G09G 2300/0842; G09G 2320/0233; G09G 2320/041

(57) ABSTRACT

A display device include a display panel having a plurality of pixels, a gate driver configured to apply a scan signal to the plurality of pixels, a data driver configured to apply a data voltage to the plurality of pixels through a data line, a power supply unit configured to apply a driving voltage to the plurality of pixels, and a timing controller configured to control an operation of the gate driver, the data driver and the power supply unit, and a method for operating the display device.

### CROSS REFERENCE TO RELATED APPLICATION

This application claims priority from and the benefit of Korean Patent Application No. 10-2025-0035009, filed on March 19, 2025, which is hereby incorporated by reference for all purposes as if fully set forth herein.

### BACKGROUND

### Field

Embodiments of the invention relate generally to a pixel, a display device, and a method for operating the display device.

### Discussion of the Background

With the progress of the information-oriented society, various types of demands for display devices which display an image are increasing. Further, various types of display devices such as a liquid crystal display device, and an organic light emitting display device have been used.

The organic light emitting display device improves lifespan and efficiency by applying a light emitting element in a tandem structure. The organic light emitting display device in a tandem structure includes a first emission layer, a charge generation layer (CGL), and a second emission layer disposed between an anode electrode and a cathode electrode.

The organic light emitting display device in a tandem structure requires a high driving voltage because current density is reduced as a number of a stack increases and as a result, charging/discharging is not properly performed, and an operating point voltage increases.

The above information disclosed in this Background section is only for understanding of the background of the inventive concepts, and, therefore, it may contain information that does not constitute prior art.

### SUMMARY

A display device includes a light emitting display panel in a tandem structure having a plurality of light emission units and having a transistor which uses a ground voltage as a source electrode of a driving transistor, and a method for operating a display device.

A display device which programs a data voltage using a ground voltage during a programming period, and boosts a programmed voltage using a reference voltage during a boosting period, and a method for operating the display device including pixels is provided.

A display device which electrically connect a cathode electrode and a low potential driving voltage to each other using an auxiliary electrode, and apply a ground voltage or a low potential driving voltage equivalent thereto to a pixel through the auxiliary electrode, and a method for operating the display device including pixels is provided.

A a display device which vary a reference voltage according to a temperature of a display panel and a method for operating the display device including pixels is provided.

Additional features of the inventive concepts will be set forth in the description which follows, and in part will be apparent from the description, or may be learned by practice of the inventive concepts.

According to one embodiment, a display device includes: a display panel having a plurality of pixels; a gate driver configured to apply a scan signal to the plurality of pixels; a data driver configured to apply a data voltage to the plurality of pixels through a data line; a power supply unit configured to apply a driving voltage to the plurality of pixels; and a timing controller configured to control an operation of the gate driver, the data driver and the power supply unit.

Each of the plurality of pixels may include: a light emitting element formed of a plurality of light emission units; a driving transistor having a first electrode connected to a high potential driving voltage, a gate electrode connected to a first node, and a second electrode connected to an anode electrode of the light emitting element through a second node; a first transistor connected between the data line and the first node and having a gate electrode configured to receive a first scan signal; a second transistor connected between a readout line to which a reference voltage is applied and the second node and having a gate electrode configured to receive a second scan signal through a gate electrode of the second transistor; a third transistor having a first electrode connected to a first voltage, and a second electrode connected to the second node, and a gate electrode configured to receive the first scan signal; and a storage capacitor connected between the first node and the second node.

The plurality of light emission units may be connected in series through a charge generation layer, and the reference voltage may be set to a voltage value in a range from about 70% to about 95% of a turn-on voltage of the light emitting element.

The first voltage may include a ground voltage, and the first transistor and the third transistor are configured to apply a data voltage and the first voltage to the first node and the second node, respectively, in a first period in one frame in response to the first scan signal in a turn-on level.

The second transistor may be configured to apply the reference voltage to the second node in response to the second scan signal in a turn-on level in the second period after the first period.

The data voltage which is a voltage difference between the first node and the second node may be programmed into each of the plurality of pixels in the first period,

A voltage of the second node and the first node coupled to the second node may be boosted in response to the reference voltage in the second period and an electron and a hole previously charged may be discharged in the light emitting element in response to the reference voltage.

The reference voltage may be configured to be varied on a frame basis in correspondence with a sensing result of electric characteristics of each of the plurality of pixels.

The reference voltage may be configured to be varied in inverse proportion to a temperature of each of the plurality of pixels.

The display device may further include: a substrate including an emission region having the light emitting element and a non-emission region around the emission region; the driving transistor and the third transistor formed on the substrate; an auxiliary electrode formed on the substrate and disposed in the non-emission region; an inter-layer insulating stack formed on the driving transistor, the third transistor and the auxiliary electrode; and the light emitting element disposed on the inter-layer insulating stack and including the anode electrode, an emission layer and a cathode electrode.

The cathode electrode may be electrically connected to the auxiliary electrode through a contact hole penetrating the inter-layer insulating stack.

The first electrode of the third transistor may be integrally formed with the auxiliary electrode.

In the contact hole, an undercut may be formed in at least one region, and the cathode electrode and the auxiliary electrode may be in contact with each other in a region overlapping the undercut in a thickness direction.

The first electrode of the third transistor may receive the first voltage or a low potential driving voltage through the auxiliary electrode.

The light emitting element may be a tandem light emitting element formed of a multiple-stack including at least three light emission units.

The undercut may be formed by recessing an inner side surface of the contact hole.

According to another embodiment, a method for operating a display panel having a plurality of pixels, a gate driver configured to apply a scan signal to the plurality of pixels, a data driver configured to apply a data voltage to the plurality of pixels through a data line, a power supply unit configured to apply a driving voltage to the plurality of pixels, and a timing controller configured to control an operation of the gate driver, the data driver and the power supply unit, wherein each of the plurality of pixels includes: a light emitting element formed of a plurality of light emission units; a driving transistor having a first electrode connected to a high potential driving voltage, a gate electrode connected to a first node, and a second electrode connected to an anode electrode of the light emitting element through a second node; a first transistor connected between the data line and the first node and having a gate electrode configured to receive a first scan signal; a second transistor connected between a readout line to which a reference voltage is applied and the second node and having a gate electrode configured to receive a second scan; a third transistor having a first electrode connected to a first voltage, a second electrode connected to the second node, and a gate electrode configured to receive the first scan signal; and a storage capacitor connected between the first node and the second node, the method includes: applying the first scan signal in a turn-on level and applying a data voltage to the data line in a first period in an active period in one frame; converting the first scan signal into a turn-off level and applying the second scan signal in a turn-on level in a second period; and applying the second scan signal in a turn-off level in the third period.

The method may further include: applying the second scan signal in a turn-on level and applying a reference voltage for sensing to the second node in a fourth period in a blank period after an active period; obtaining sensing data from an electric signal output through the readout line in a fifth period; and varying the reference voltage based on the obtained sensing data.

The varying of the reference voltage may include: determining a temperature of each of the plurality of pixels based on the obtained sensing data; selecting a voltage value corresponding to the determined temperature from a prestored look-up table; and varying the reference voltage to the selected voltage value.

The reference voltage may be set to be a voltage value in a range from about 70% to about 95% of a turn-on voltage of the light emitting element, and the turn-on voltage of the light emitting element may increase in correspondence with a quantity of the light emission units.

According to still another embodiment, a pixel includes: a substrate including an emission region and a non-emission region around the emission region; at least one thin film transistor formed on the substrate; an auxiliary electrode formed on the substrate and disposed in the non-emission region; an inter-layer insulating stack formed on the at least one thin film transistor and the auxiliary electrode; and a light emitting element formed on the inter-layer insulating stack in a thickness direction, disposed in the emission region, and having an anode electrode, a plurality of light emission units, a charge generation layer interposed between the plurality of light emission units, and a cathode electrode which are stacked.

The at least one thin film transistor may include: a driving transistor including a first electrode connected to a high potential driving voltage, a gate electrode connected to a first node and a second electrode connected to the anode electrode through a second node; and a switching transistor including a first electrode connected to a first voltage and a second electrode connected to the second node.

The cathode electrode may be electrically connected to the auxiliary electrode through a contact hole penetrating the inter-layer insulating stack.

The first electrode of the switching transistor may be electrically connected to the auxiliary electrode.

In the contact hole, an undercut may be formed in at least one region, and the cathode electrode and the auxiliary electrode may be in contact with each other in a region overlapping the undercut.

The light emitting element may be a tandem light emitting element formed of a multiple-stack including at least three light emission units.

The at least one thin film transistor may further include: a sensing transistor connected between a reference voltage and the second node, and the reference voltage may be set to be a voltage value in a range from about 70% to about 95% of a turn-on voltage of the light emitting element.

The undercut is formed by recessing an inner side surface of the contact hole.

According to still another embodiment, a method of driving a plurality of pixels of a display device, each pixel including a driving transistor, a light emitting element, a first transistor, a second transistor, a third transistor, and a storage capacitor, the method comprising: applying a first scan signal at a turn-on level to gate electrodes of the first transistor and the third transistor during a first period of one frame to turn on the first transistor and the third transistor; applying a data voltage to a first node through the first transistor, and applying a first voltage to a second node through the third transistor during the first period; applying a second scan signal at a turn-on level to a gate electrode of the second transistor during a second period to turn on the second transistor; and applying a reference voltage to the second node during the second period; driving the light emitting element during a third period based on a gate-to-source voltage of the driving transistor formed according to a voltage difference stored between the first node and the second node; in which the reference voltage is adjustable in accordance with operating conditions of the pixels.

A pixel, a display device, and a method for operating the display device according to embodiments may drive a pixel using a data voltage in a low voltage value range even if a number of a stack of a tandem light emitting element increases. As a result, a pixel, a display device, and a method for operating the display device according to embodiments may prevent fast deterioration of a circuit element and reduce power consumption and manufacturing costs.

A pixel, a display device, and a method for operating the display device according to embodiments may effectively perform discharging of a light emitting element while not increasing power consumption, by applying a sufficiently high operating point voltage to a tandem light emitting element while at the same time, using a data voltage in a low voltage value range.

A pixel, a display device, and a method for operating the display device according to embodiments may prevent rapid charging of a light emitting element by increasing a driving voltage of a light emitting element by stages while the display is driven.

A pixel, a display device, and a method for operating the display device according to embodiments may prevent image quality deterioration in a low grayscale by efficiently performing discharging of a light emitting element while at the same time, reducing a resistance with respect to a low potential driving voltage applied to a cathode electrode of a light emitting element.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic block diagram of a configuration of a display device according to an embodiment.

FIGS. 2 and 3 are schematic diagrams illustrating a structure of a light emitting element according to one or more embodiments.

FIG. 4 is a schematic diagram illustrating current density according to a number of a stack of a tandem element.

FIG. 5 is a schematic circuit diagram illustrating a pixel according to an embodiment.

FIG. 6 is a schematic diagram illustrating a method for operating a pixel illustrated in FIG. 5 according to an embodiment.

FIG. 7 is a schematic diagram illustrating a connection relationship of a timing controller, a data driver, and a pixel according to an embodiment.

FIG. 8 is a schematic diagram illustrating a change of an operating point voltage of a light emitting element according to a temperature.

FIG. 9 is a schematic diagram illustrating a method for operating a pixel illustrated in FIG. 7 according to an embodiment.

FIG. 10 is a schematic plan view of one region of a display device according to an embodiment.

FIG. 11 is a schematic cross-sectional view illustrating a stacked shape of a display device according to an embodiment.

### DETAILED DESCRIPTION

In the following description, for the purposes of explanation, numerous specific details are set forth in order to provide a thorough understanding of one or more embodiments or implementations of the invention. As used herein “embodiments” and “implementations” are interchangeable words that are non-limiting examples of devices or methods employing one or more of the inventive concepts disclosed herein. It is apparent, however, that one or more embodiments may be practiced without these specific details or with one or more equivalent arrangements. In other instances, well-known structures and devices are shown in block diagram form in order to avoid unnecessarily obscuring one or more embodiments. Further, one or more embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the one or more embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

One or more embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

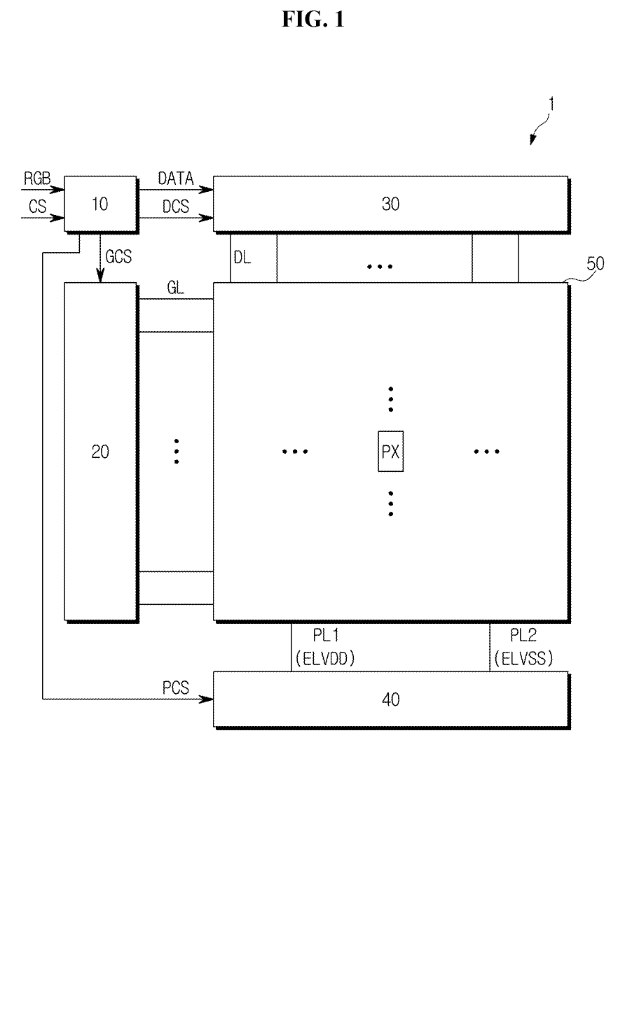

FIG. 1 is a schematic block diagram of a configuration of a display device according to an embodiment.

Referring to FIG. 1, a display device 1 may include a timing controller 10, a gate driver 20, a data driver 30, a power supply unit 40, and a display panel 50.

The timing controller 10 may be configured by being integrated to various processors, for example, a micro-processor, a mobile processor, an application processor, and the like according to devices mounted therein. The timing controller 10 may receive a video signal RGB and a control signal CS from an external host system and the like. The video signal RGB may include a plurality of grayscale data. The control signal CS may include, for example, a horizontal synchronization signal, a vertical synchronization signal and a main clock signal.

The timing controller 10 may process the video signal RGB and the control signal CS to be suitable to operational conditions of the display panel 50, and may generate and output image data DATA, a gate driving control signal GCS, a data driving control signal DCS, and a power supply control signal PCS.

The gate driver 20 may generate scan signals based on a gate driving control signal GCS output from the timing controller 10. The gate driver 20 may provide the generated scan signals to the plurality of pixels PX through a plurality of gate lines GL. In an embodiment, one pixel PX may be configured to receive a plurality of scan signals having different waveforms. In such an embodiment, the gate driver 20 may provide the plurality of scan signals to the plurality of pixels PX through the gate lines GL corresponding thereto, respectively.

The gate driver 20 may be configured in a Gate-In-Panel form in which the gate driver 20 is mounted on the display panel 50. The gate driver 20 may be disposed on one side of the display panel 50, or on both sides (for example, left and right sides) of the display panel 50. According to a driving method, a panel design manner, and the like, the gate driver 20 may be disposed on both sides (for example, left and right sides) of the display panel 50 as illustrated, or may be electrically connected to two or more side surfaces among four side surfaces of the display panel 50.

The data driver 30 may generate data signals based on the data driving control signal DCS and image data DATA output from the timing controller 10. The data driver 30 may provide the generated data signals to the plurality of pixels PX through a plurality of data lines DL.

The power supply unit 40 may generate a high potential driving voltage ELVDD and a low potential driving voltage ELVSS to be provided to the display panel 50 based on the power supply control signal PCS. The power supply unit 40 may provide the generated driving voltages ELVDD and ELVSS to the plurality of pixels PX through corresponding power lines PL1 and PL2. In addition, the power supply unit 40 may further generate a reference voltage and the like required for driving each of the plurality of pixels PX, and provide it to the plurality of pixels PX through a corresponding voltage line.

The display panel 50 may be implemented as a transmissive or a non-transmissive display panel. The transmissive display panel may be applied to a transparent display device of which an image is displayed in the screen and a real background object is visible. The display panel 50 may be manufactured as a flexible display panel. The flexible display panel may be implemented as an OLED panel which uses a plastic substrate.

On the display panel 50, the plurality of pixels PX (or referred to as sub-pixels) may be disposed. The plurality of pixels PX may be disposed, for example, in a matrix form on the display panel 50. The plurality of pixels disposed in one pixel row may be electrically connected to the same gate line GL, and the plurality of pixels PX disposed in one pixel column may be electrically connected to the same data line DL. The plurality of pixels PX may emit light at luminance corresponding to a data signal and a scan signal supplied through the data line DL and the gate line GL.

Each pixel PX may include the light emitting element and a driving circuit configured to drive the light emitting element. The light emitting element included in the pixel PX may display one color among red, green and blue. In another embodiment, the light emitting element may display one color among cyan, magenta and yellow. In one or more embodiments, the light emitting element may display one color among red, green, blue and white.

In an embodiment, the pixel PX may be a tandem element of which a plurality of light emission units are electrically connected in series. Hereinafter, the tandem element will be described in more detail.

In an embodiment, a touch sensor may be further disposed on the display panel 50. A touch input may be sensed using additional touch sensors or may be sensed through pixels PX. The touch sensors may be disposed on the screen of the display panel 50 in an on-cell type or an add-on type, or may be implemented as in-cell type touch sensors embedded to the display panel 50.

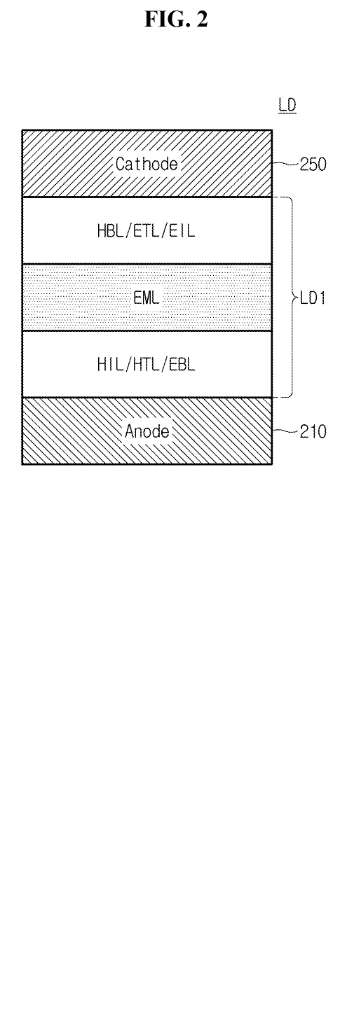

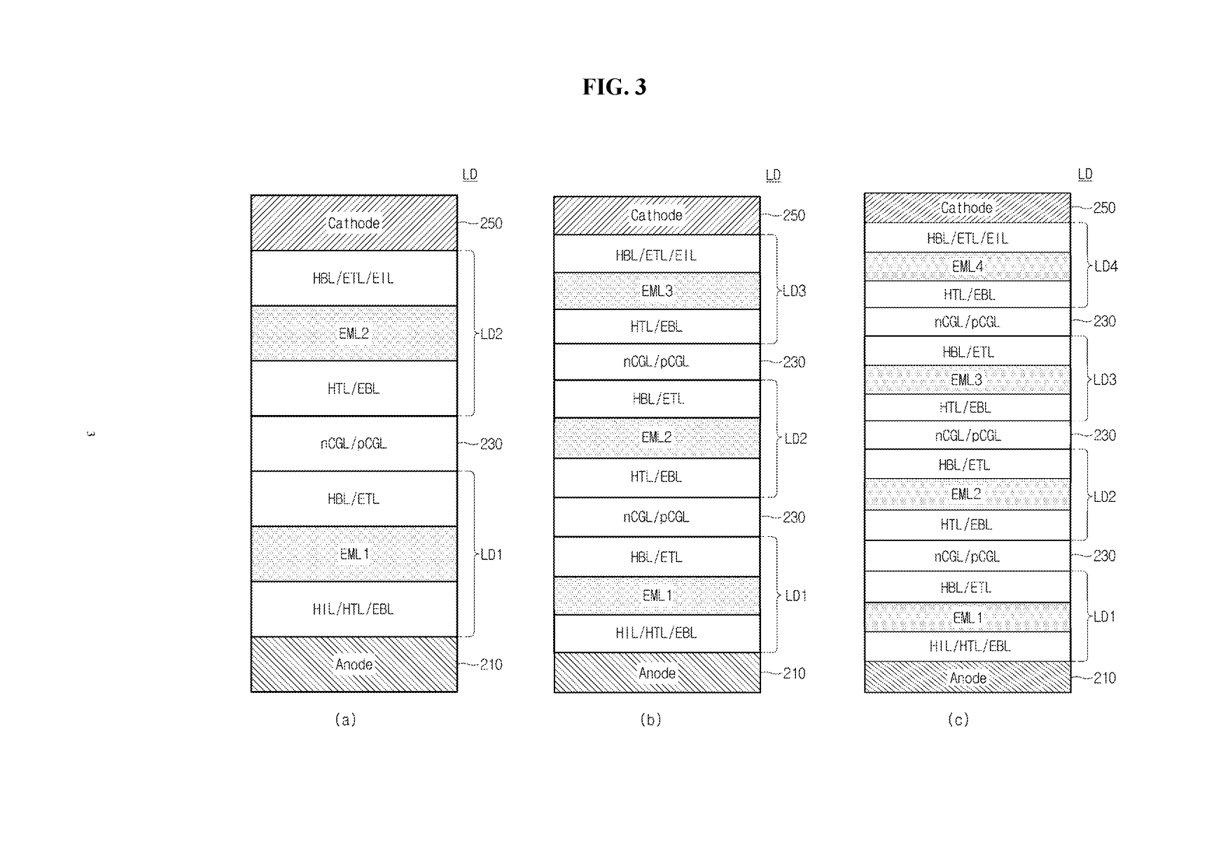

FIGS. 2 and 3 are schematic diagrams illustrating a structure of the light emitting element according to one or more embodiments.

Referring to FIG. 2, the light emitting element LD in an embodiment may include a first electrode 210 and a second electrode 250 opposed to each other, and a light emission unit LD1 disposed between the first electrode 210 and the second electrode 250. Here, the first electrode 210 may be an anode electrode and the second electrode 250 may be a cathode electrode.

In an embodiment, the light emission unit LD1 may include an emission layer EML. The light emission layer EML may include a light emitting material emitting light in a predetermined color. The emission layer EML may include, for example, a blue light emitting material B, a red light emitting material R, and a green light emitting material G, but is not limited thereto.

The light emission unit LD1 may further include at least one organic layer interposed between the first electrode (or anode) 210 and the emission layer EML. For example, the organic layer may include a hole injection layer (HIL), a hole transport layer (HTL), an electron block layer (EBL), and the like.

In addition, the light emission unit LD1 may further include at least one organic layer interposed between the emission layer EML and the second electrode (or cathode) 250. For example, the organic layer may include an electron injection layer (EIL), an electron transport layer (ETL), a hole block layer (HBL), and the like.

Such a structure of the light emission unit LD1 may be referred to as a one-stack (1-stack) structure in which the emission layer EML is configured of one layer.

Referring to (a) of FIG. 3, in another embodiment, the light emitting element LD may have a tandem structure in which two light emission units LD1 and LD2 are electrically connected in series and emit light. In more detail, the light emitting element LD may include the first electrode 210 and the second electrode 250 opposed to each other, a first light emission unit LD1 and a second light emission unit LD2 disposed between the first electrode 210 and the second electrode 250, and a charge generation layer 230 disposed between the first light emission unit LD1 and the second light emission unit LD2. The first light emission unit LD1 may be disposed adjacent to the first electrode 210, and the second light emission unit LD2 may be disposed adjacent to the second electrode 250.

The first light emission unit LD1 may include a first emission layer EML1, and the second light emission unit LD2 may include a second emission layer EML2. The first light emission unit LD1 and the second light emission unit LD2 may include a plurality of light emitting materials emitting light in different colors.

For example, each of the first emission layer EML1 and the second emission layer EML2 may include a blue light emitting material B, a red light emitting material R, and a green light emitting material G. Each of the light emitting materials R, G and B may be formed per region in the emission layers EML1 and EML2.

In an embodiment, the first light emission unit LD1 may further include at least one organic layer interposed between the first electrode (or anode) 210 and the first emission layer EML1. For example, the organic layer may include a hole injection layer (HIL), a hole transport layer (HTL), an electron block layer (EBL), and the like.

In addition, the first light emission unit LD1 may further include at least one organic layer interposed between the first emission layer EML1 and the second light emission unit LD2. For example, the organic layer may include an electron transport layer (ETL), a hole block layer (HBL), and the like.

In an embodiment, the second light emission unit LD2 may further include at least one organic layer interposed between the first light emission unit LD1 and the second emission layer EML2. For example, the organic layer may include a hole transport layer (HTL), an electron block layer (EBL), and the like.

In addition, the second light emission unit LD2 may further include at least one organic layer interposed between the second emission layer EML2 and the second electrode (or cathode) 250. For example, the organic layer may include an electron transport layer (ETL), an electron injection layer (EIL), a hole block layer (HBL), and the like.

The charge generation layer 230 may be further disposed between the light emission units LD1 and LD2. The charge generation layer 230 may adjust charges between the light emission units LD1 and LD2, and keep a balance of charges. The charge generation layer 230 may include a negative charge generation layer (an n-type charge generation layer, nCGL) positioned adjacent to the first light emission unit LD1 and configured to supply electrons to the first light emission unit LD1, and a positive charge generation layer (a p-type charge generation layer, pCGL) positioned adjacent to the second light emission unit LD2 and configured to supply holes to the second light emission unit LD2.

Such a structure of the light emitting element LD may be referred to as a two-stack structure in which the emission layers EML1 and EML2 are formed of two layers.

In one or more embodiments, the light emitting element LD may have a stack structure formed of two stacks or more. For example, the light emitting element LD may have a three-stack structure in which three emission layers EML are stacked as illustrated in (b) in FIG. 3, or a four-stack structure in which four emission layers EML are stacked as illustrated in (c) in FIG. 3, or a structure of more than four stacks.

In an embodiment, the light emitting element LD in the tandem structure may be a pure-color tandem structure formed of a light emitting material in a pure color such as red, blue or green, or a tandem structure in which the light emitting materials in a yellow-green color and the like are mixed. For example, the light emitting element LD may be a light emitting element of a phosphor-fluorescent two-tandem structure which is a structure of a white organic light emitting diode, in which, a first stack which uses a blue fluorescent element as an emission layer and a second stack which uses a yellow-green phosphorescent element as an emission layer, are stacked. The white organic light emitting diode may implement a white light by an effect of mixed light obtained by mixing a blue light emitted from the blue fluorescent element and a yellow-green light emitted from the yellow-green phosphorescent element.

In another embodiment, the light emitting element LD in the tandem structure may be a light emitting element in a phosphor-fluorescent three-tandem structure to which a third stack which uses a blue fluorescent element as an emission layer is additionally applied. In such an embodiment, the light emitting element may be formed to have three-emission peaks by applying an emission layer in a phosphorescent red color and a phosphorescent yellow-green to the second-stack in a three-tandem white organic light emitting diode structure.

The structure of the light emitting element LD is not limited to the described ones, and may be changed variously. For example, in other embodiments, the light emitting element LD may have more than four-stack structure.

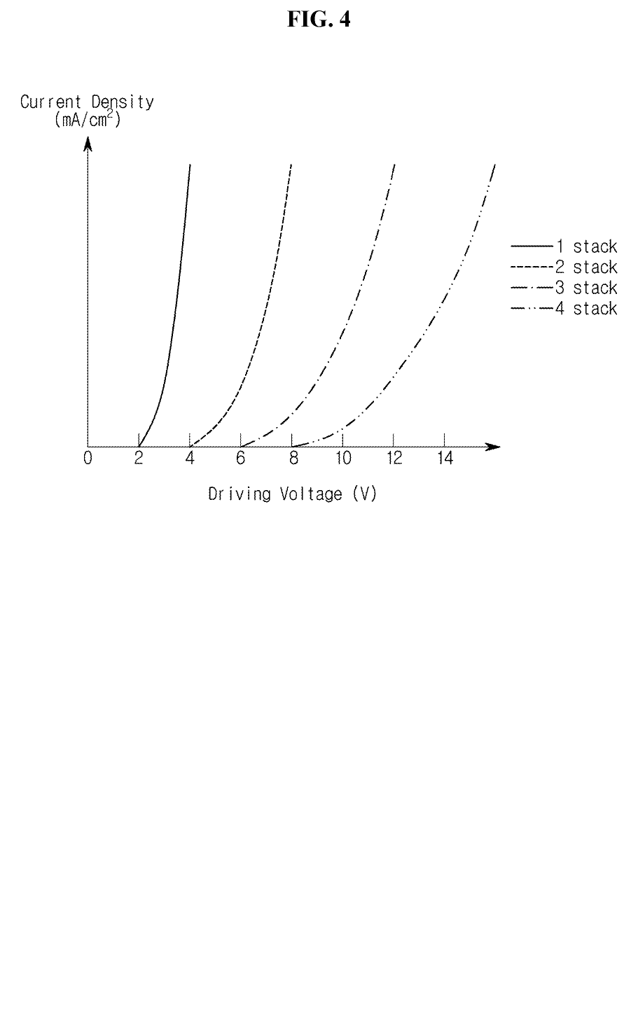

FIG. 4 is a schematic diagram illustrating current density according to a number of a stack of the tandem element.

Referring to FIGS. 2 and 4 together, current density of the light emitting element LD may increase in correspondence with a voltage between the anode electrode 210 and the cathode electrode 250 of the light emitting element LD, in particular, a magnitude of the driving voltage. Here, the current density may mean a magnitude of a current flowing per unit area.

In case of the tandem element having different kinds of emission layers and a plurality of stacks, because of electric interference and increase in the resistance between different kinds of emission layers, a greater driving voltage is required so as to implement the same current density. In particular, when applying the same driving voltage to the light emitting element LD, a movement speed of the electron-hole of a multi-stack light emitting element LD decreases compared to a movement speed of the electron-hole of a one stack light emitting element LD.

Such a reduction of the current density boosts the operating point voltage (in particular, a turn-on voltage, a turn-off voltage) of the light emitting element LD. For example, when the turn-on voltage of the one-stack light emitting element LD is about 1.5V, the turn-on voltage of the four-stack light emitting element LD may increase up to about 7.5V.

When initializing the light emitting element by applying the turn-off voltage to the light emitting diode LD, the one-stack light emitting element LD may have a relatively high current density (in particular, the electron-hole movement speed), and the electron and the hole charged therein may be sufficiently discharged. On contrary, the four-stack light emitting element LD may have a relatively low current density with respect to the same turn-off voltage, and the electron and the hole charged therein may not be discharged to the fullest.

Such an insufficient discharge of the electron and the hole may occur intensively in the light emitting element LD of at least three or more stacks, and may become a problem in the light emitting element of four or more stacks.

Residual electron and hole may generate unwanted emission by a voltage applied to the light emitting element LD, and this causes deterioration of image quality in a low grayscale image in which the emission visibility is particularly high. Therefore, in order to make a complete discharge of the light emitting element LD, a sufficiently high turn-off voltage must be applied to the light emitting element of a multiple stack structure.

The driving voltage applied to the light emitting element LD may be determined according to the gate-source voltage of the driving transistor provided in the pixel PX (FIG. 1). Therefore, in order to apply a great driving voltage to the light emitting element LD, a range of voltages determining the gate-source voltage of the driving transistor (for example, a data voltage and a reference voltage) must rise to a range of a high potential voltage value. Such increase of the driving voltage may reduce lifespan by accelerating deterioration of the circuit element and may increase power consumption and manufacturing costs by increasing an output voltage of the data driver 30 (FIG. 1).

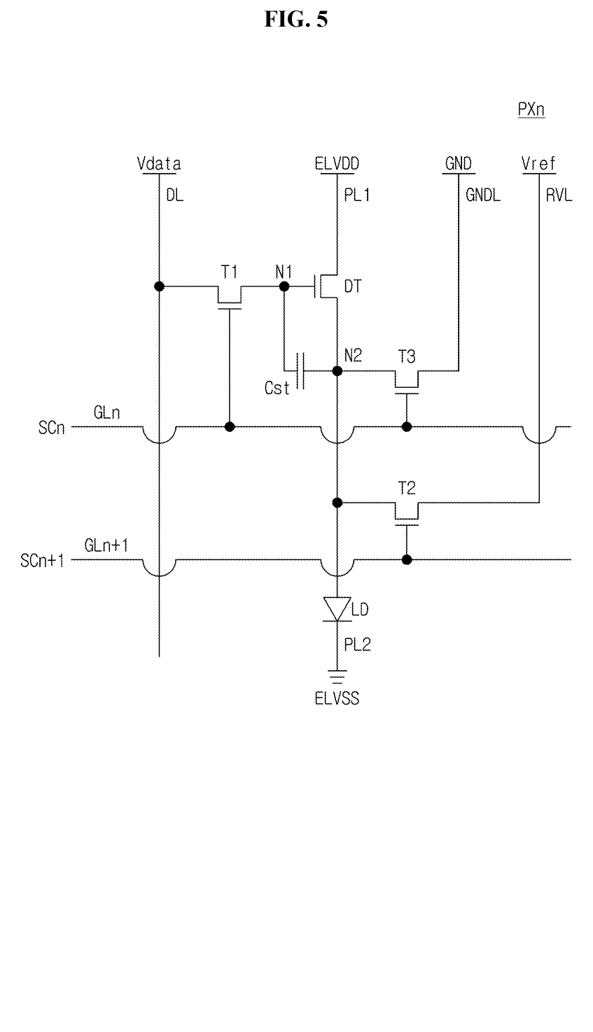

FIG. 5 is a schematic circuit diagram illustrating the pixel according to an embodiment. In an embodiment in FIG. 5, a pixel PXn disposed in an n-th pixel row is taken as an example. Here, n is a random natural number equal to or greater than 1 and smaller than or equal to a quantity of the entire pixel rows.

Referring to FIG. 5, the pixel PXn according to an embodiment may include a driving transistor DT, a light emitting element LD electrically connected to the driving transistor DT, and a control circuit configured to control an amount of the driving current to be applied to the light emitting element LD through the driving transistor DT. For example, the control circuit may include first, second, and third transistors T1, T2, and T3 and a storage capacitor Cst. In another embodiment, the control circuit may include more than three or less than three transistors.

A first electrode of the driving transistor DT may be configured to receive a high potential driving voltage ELVDD (electrically connected to a high potential driving voltage line PL1), and a second electrode may be electrically connected to the light emitting element LD through a second node N2. A gate electrode of the driving transistor DT may be electrically connected to the data line DL through a first node N1. The driving transistor DT may be turned on according to a voltage difference between the first node N1 and the second node N2 (in particular, a gate-source voltage) and may control an amount of the driving current flowing to the light emitting element LD.

The first electrode of the first transistor T1 may be electrically connected to the data line DL, and the second electrode may be electrically connected to the gate electrode of the driving transistor DT through the first node N1. A gate electrode of the first transistor T1 may be electrically connected to a first gate line GLn and may receive a first gate signal SCn. Here, the first gate line GLn may be an n-th gate line GLn which applies an n-th scan signal SCn to the first transistor T1 of the plurality of pixels PXn disposed in the n-th pixel row.

The first transistor T1 may be turned on according to a first scan signal SCn applied to the first gate line GLn, and may deliver a data voltage Vdata applied to the data line DL to the first node N1. Such a first transistor T1 may be referred to as a switching transistor.

A first electrode of the second transistor T2 may be electrically connected to the second node N2, and a second electrode may be configured to receive a reference voltage Vref (connected to a readout line RVL). A gate electrode of the second transistor T2 may be electrically connected to a second gate line GLn+1 and may receive a second gate signal SCn+1. Here, the second gate line GLn+1 may be an (n+1)th gate line GLn+1 which applies an (n+1)th scan signal SCn+1 to a first transistor T1 of pixels (not illustrated) disposed in an (n+1)th pixel row.

The second transistor T2 may be turned on according to a second scan signal SCn+1 applied to the second gate line GLn+1, and may apply the reference voltage Vref to the second electrode of the driving transistor DT. Such a second transistor T2 may be referred to as a boosting transistor or a sensing transistor.

A first electrode of the third transistor T3 may be electrically connected to the second node N2, and a second electrode may be configured to receive the ground voltage GND (connected to a ground voltage line GNDL). A gate electrode of the third transistor T3 may be electrically connected to the first gate line GLn and may receive a first scan signal SCn. The third electrode T3 may be turned on according to the first scan signal SCn applied to the first gate line GLn, and may apply the ground voltage GND to the second electrode of the driving voltage DT. Such a third transistor T3 may be referred to as a second switching transistor.

Meanwhile, in the illustrated embodiment, it is illustrated that the third transistor T3 is electrically connected to the ground voltage GND, but the embodiment is not limited thereto. In another embodiment, the third transistor T3 at 0V, or a sufficiently low voltage corresponding thereto may be electrically connected to a predetermined lower voltage than the reference voltage Vref.

Alternatively, the third transistor T3 may be electrically connected to a low potential driving voltage line PL2 together with the cathode electrode of the light emitting element LD. In an embodiment, the low potential driving voltage ELVSS may be set to about 0V or a low voltage corresponding thereto. The anode electrode of the light emitting element LD may be electrically connected to the driving transistor DT through the second node N2, and the cathode electrode may be electrically connected to the low potential driving voltage ELVSS (connected to the low potential driving voltage line PL2). When the driving transistor DT is turned on, a current path is formed between the high potential driving voltage ELVDD and the low potential driving voltage ELVSS, and a driving current may flow to the light emitting element LD. The light emitting element LD may emit light at luminance corresponding to an amount of the driving current applied thereto. In the boosting period t2, voltages of the first node N1 and the second node N2 may be boosted. In more detail, in the boosting period t2, the first scan signal SCn may be changed over to a turn-off level, and the second scan signal SCn+1 in a turn-on level may be applied. Accordingly, the first transistor T1 and the third transistor T3 may be turned off, and the second transistor T2 may be turned on.

The storage capacitor Cst may be electrically connected between the first node N1 and the second node N2. The storage capacitor Cst may store a voltage corresponding to a voltage difference between the first node N1 and the second node N2, and maintain the stored voltage during one frame period, thereby stabilizing a voltage of the gate electrode (in particular, the first node N1) of the driving transistor DT.

In an embodiment, the light emitting element LD may have a tandem structure in which a plurality of light emission units are connected in series. The light emitting element LD may improve light emission purity and light emission efficiency by having a structure in which a plurality of light emission units are stacked.

In the embodiment illustrated in FIG. 5, the pixel PXn may include an oxide semiconductor transistor. The oxide semiconductor transistor may include a gate electrode, a source electrode, and a drain electrode. The oxide semiconductor transistor may have an active layer formed of an oxide semiconductor.

Here, the oxide semiconductor may be set as an amorphous oxide semiconductor or a crystalline oxide semiconductor. The oxide semiconductor transistor may be configured as an n-type transistor. The oxide semiconductor transistor may be formed through a low temperature process and may have a lower charge mobility than that of the LTPS transistor. Such an oxide semiconductor transistor may have an excellent off current characteristic.

In another embodiment, the pixel PXn may be a hybrid type further including the LTPS (Low Temperature Poly-Silicon) transistor.

The LTPS transistor may include a gate electrode, a source electrode, and a drain electrode. The LTPS transistor may have an active layer formed of poly silicon. Such an LTPS transistor may be configured as a P-type transistor or an N-type transistor. The LTPS transistor may have a high electron mobility, and therefore, may have a fast driving characteristic.

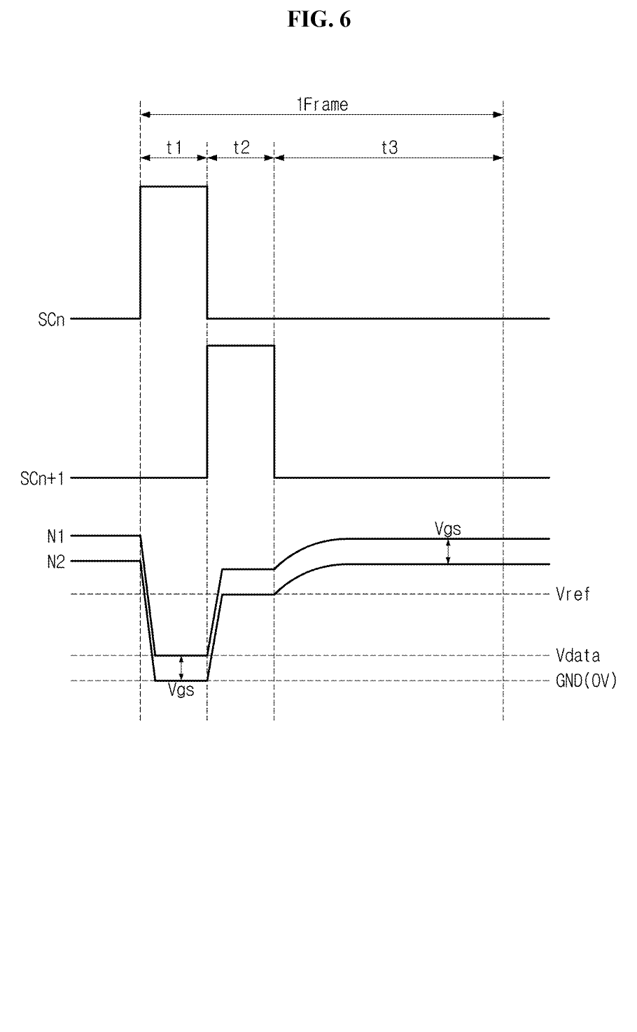

FIG. 6 is a schematic diagram illustrating a method for operating the pixel illustrated in FIG. 5 according to an embodiment.

Referring to FIGS. 5 and 6 together, one frame (1 Frame) may include a programming period t1, a boosting period t2, and a light emitting period t3.

In the programming period t1, the data voltage Vdata may be programmed into the pixel PXn. In more detail, in the programming period t1, the first scan signal SCn in a turn-on level may be applied and the first transistor T1 and the third transistor T3 may be turned on.

As the first transistor T1 is turned on, the data voltage Vdata may be applied to the gate electrode of the driving transistor DT. In addition, as the third transistor T3 is turned on, the ground voltage GND may be applied to the source electrode of the driving transistor DT.

In the programming period t1, the gate-source voltage of the driving transistor DT may be programmed into the data voltage Vdata. At this instance, the gate-source voltage may be a voltage which may turn on the driving transistor DT, and the driving transistor DT may be turned on. The data voltage Vdata which is programmed may be stored in the storage capacitor Cst.

The reference voltage Vref may be applied to the second node N2 through the second transistor T2 which is turned on.

In an embodiment, the reference voltage Vref may be set to a voltage value between the ground voltage GND and the operating point voltage of the light emitting element LD. For example, the reference voltage Vref may be set to a value in a range from about 70% to about 95% of the operating point voltage of the light emitting element LD in consideration of a change in the operating point of the light emitting element LD according to an operating environment (for example, a temperature and the like) of the pixel PXn, but is not limited thereto.

In an embodiment, a voltage value of the reference voltage Vref may be set to a fixed value. In another embodiment, the reference voltage Vref may be varied while the display panel 50 (FIG. 1) is driven. For example, the reference voltage Vref may be varied according to a temperature, a driving period, a degree of deterioration and the like of the pixel PXn.

At this instance, the reference voltage Vref may be varied in a range from about 70% to about 95% of the operating point voltage of the light emitting element LD. The embodiment will be described in more detail with reference to drawings below.

In the boosting period t2, a voltage of the second node N2 may be boosted from the ground voltage GND up to the reference voltage Vref. A voltage of the first node N1 coupled to the second node N2 by the storage capacitor Cst may be boosted in correspondence with a voltage rise of the second node N2. A voltage difference between the first node N1 and the second node N2 may be maintained to be a voltage programmed in the programming period t1, in particular, the data voltage Vdata.

Meanwhile, as the reference voltage Vref is a voltage lower than the operating point voltage of the light emitting element LD, the light emitting element LD may not emit light in the boosting period t2. Instead, the electron and the hole previously charged in the light emitting element LD may be sufficiently discharged in response to the reference voltage Vref close to the operating point voltage of the light emitting element LD.

The light emitting element LD which is turned on in the light emitting period t3 may emit light at luminance of a magnitude corresponding to the programmed voltage. In more detail, the second scan signal SCn+1 may be changed over to a turn-off level in the light emitting period t3.

Through the driving transistor DT in a turn-on state, a driving current may flow from the high potential driving voltage ELVDD to the light emitting element LD via the driving transistor DT. The voltage of the second node N2 may be boosted to the operating point voltage of the light emitting element LD.

At this instance, the gate-source voltage of the light emitting element LD may be maintained to be a voltage programmed by the storage capacitor Cst. The light emitting element LD emits light by the driving current when the voltage of the second node N2 becomes equal to the operating point voltage.

According to the driving manner described above, in the programming period t1, a voltage of the source electrode of the driving transistor DT may be held to be the ground voltage GND or a low potential voltage equivalent to the ground voltage GND through the third transistor T3. Therefore, the data voltage Vdata applied to the gate electrode of the driving transistor DT may be set to be a voltage corresponding to emission luminance, irrelevant to the operating point voltage of the light emitting element LD. Thereafter, by boosting the gate-source voltage of the driving transistor DT through application of the reference voltage Vref, the light emitting element LD may be turned on fast in the light emitting period t3.

In such an embodiment, the pixel PXn may implement emission at desired luminance without increasing the data voltage Vdata, even if the light emitting element LD is configured to be a tandem element and has a high operating point voltage. In addition, by increasing the driving voltage of the light emitting element LD by stages in the programming period t1 and the boosting period t2, rapid charging of the electron and the hole of the light emitting element LD may be prevented. In addition, by applying the reference voltage Vref in a sufficiently high level to the light emitting element LD in advance prior to the light emitting period t3, the previously charged electron and the hole of the light emitting element LD may be discharged sufficiently, and unwanted emission and deterioration of image quality due to low luminance may be prevented. Such a technical effect may be applied so as to prevent insufficient discharge and unwanted emission in the multi-stack tandem light emitting element LD formed of three or more stacks, and may be more effective in the light emitting element LD of four or more stacks, in particular.

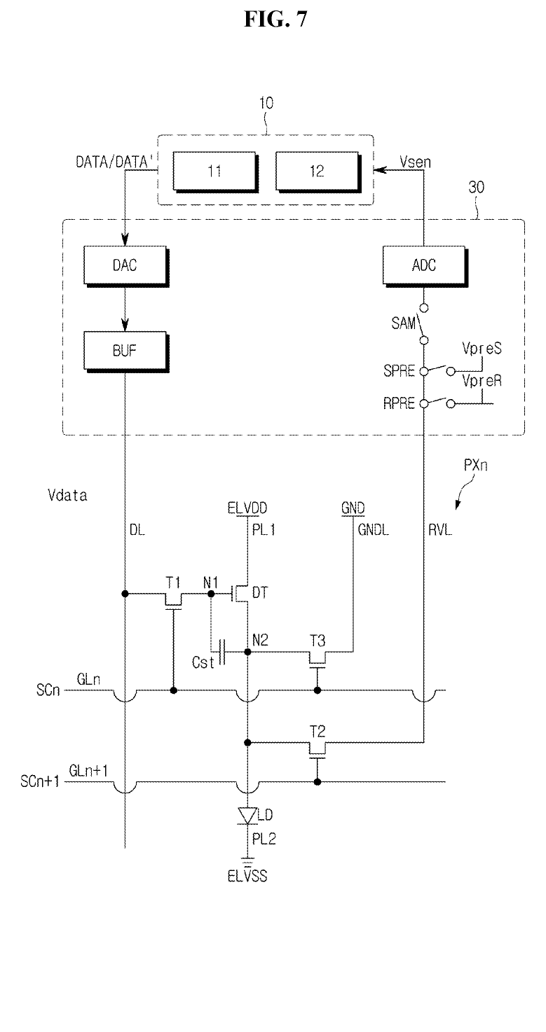

FIG. 7 is a schematic diagram illustrating a connection relationship of the timing controller, the data driver, and the pixel according to an embodiment. In an embodiment in FIG. 7, the structure of the pixel PXn is the same as that illustrated in FIG. 5, and detailed description will be omitted.

Referring to FIG. 7, in an embodiment, the display device 1 (FIG. 1) may include a compensating unit 11 configured to determine a characteristic value of the pixel PXn using sensing data Vsen obtained through sensing of the pixel PXn and perform a compensation process for compensating the characteristic value, a memory 12 configured to store a compensation value generated in the compensating unit 11 and the like. The compensating unit 11 and the memory 12 may be provided inside the timing controller 10.

In such an embodiment, the data driver 30 may further include an analog-digital converter ADC configured to convert a voltage measured through the readout line RVL into digital data, a sampling switch SAM configured to control connection between the ADC and the readout line RVL, a reference voltage switch for displaying RPRE configured to control connection between the readout line RVL and a reference voltage for displaying VpreR, and a reference voltage switch for sensing SPRE configured to control connection between the readout line RVL and a reference voltage for sensing VpreS.

The reference voltage switch for sensing SPRE and the reference voltage switch for displaying RPRE may be provided separately, or may be implemented by being integrated into one. The reference voltage for sensing VpreS and the reference voltage for displaying VpreR may have the same, or each different voltage value.

The reference voltage switch for sensing SPRE may be configured to control a voltage application state of the second node N2 of the driving transistor DT such that the second node N2 of the driving transistor DT in the pixel PXn gets into a voltage state which reflects a desired characteristic value of the circuit element. When the reference voltage switch for sensing SPRE is turned on, the reference voltage for sensing VpreS may be supplied to the readout line RVL and may be applied to the second node N2 of the driving transistor DT through the second transistor T2 which is turned on.

The sampling switch SAM may be turned on and electrically connect the readout line RVL and the analog-digital converter ADC to each other. The sampling switch SAM may be controlled to be turned on when the second node N2 in the pixel PXn gets into a voltage state which reflects a desired characteristic value of the circuit element.

When the sampling switch SAM is turned on, the analog-digital converter ADC may generate the sensing data Vsen by converting a voltage of the readout line RVL connected thereto into the digital data, and may deliver the digital data to the timing controller 10.

The analog-digital converter ADC, the sampling switch SAM, the reference voltage switch for sensing SPRE, and the reference voltage switch for displaying RPRE may be provided in the data driver 30, but is not limited thereto.

The timing controller10 may determine a characteristic value (for example, a threshold voltage, mobility and the like) of the circuit element (for example, the driving transistor DT and/or the light emitting element LD) in the corresponding pixel PXn based on the sensing data Vsen, and may perform an external compensation process with respect to the characteristic value.

In more detail, the compensating unit 11 may calculate a compensation value (for example, an offset, a gain and the like) for compensating the characteristic value based on the sensing data Vsen, and may deliver the image data DATA’ to which the compensation value is applied to the data driver 30. The data driver 30 may convert the compensated image data DATA’ into the data voltage Vdata in an analog signal form through a digital-analog converter DAC and may output the data voltage Vdata to the corresponding data line DL through an output buffer BUF. As such a characteristic value compensation is performed, luminance deviations among the plurality of pixels PXn may be reduced and the image quality may be improved.

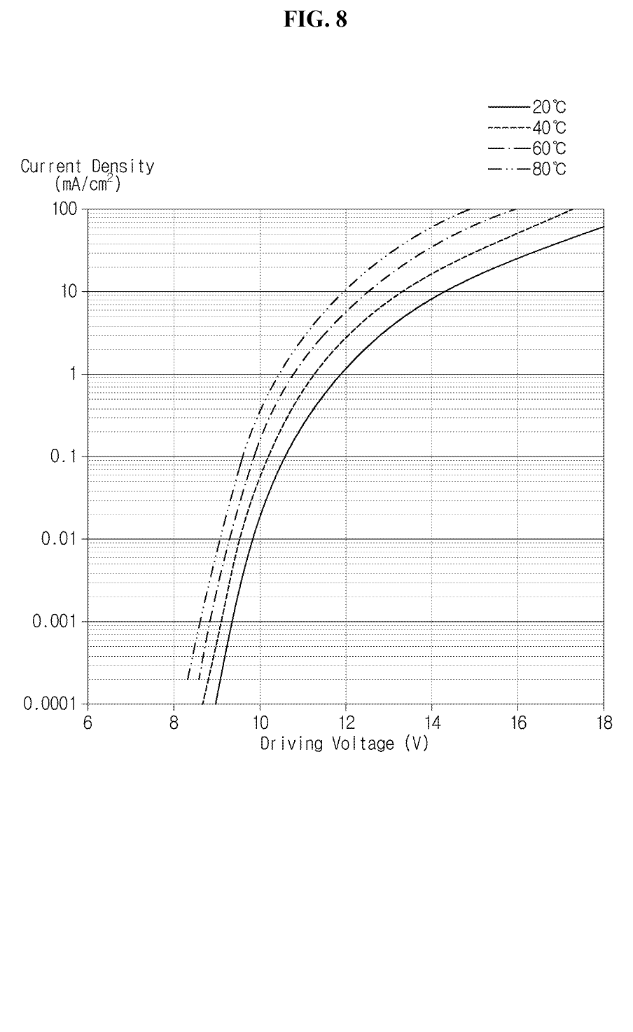

FIG. 8 is a schematic diagram illustrating a change of the operating point voltage of the light emitting element according to a temperature.

Referring to FIG. 8, the current density of the light emitting element LD with respect to the same driving voltage increases according to the temperature. In particular, the current density of the light emitting element LD may increase when the temperature increases, and more driving current may flow when the same driving voltage is applied, and thus, the light emitting element LD may emit light at higher luminance than the required luminance. Such a change of the luminance may lead to deterioration of the image quality.

In addition, when the temperature increases, the operating point voltage of the light emitting element LD may decrease. For example, when the current density is about 1×10⁻⁴ mA/cm², the operating point voltage of the light emitting element LD may decrease by about 1V when the temperature increases by 60˚C.

Decrease of the operating point voltage may cause unwanted emission of the light emitting element LD during the non-emission period. In addition, irrelevant to the variation of the operating point voltage, when using the preset reference voltage Vref, the light emitting element LD may emit light by the reference voltage Vref at an unwanted time point.

In an embodiment of FIG. 7, a value of the sensing data Vsen obtained through the data driver 30 may be determined according to a temperature of the pixel PXn, in particular, the display panel 50 (FIG. 1), and the like. For example, when the temperature of the pixel PXn increases, mobility of the driving transistor DT may increase, and the threshold voltage may decrease. Alternatively, when the temperature of the pixel PXn increases, the operating point voltage of the light emitting element LD may decrease.

Therefore, the timing controller 10 may be configured to determine the temperature of the display panel 50 and the like from the sensing data Vsen, and vary the reference voltage Vref based on the determined temperature and the like. For example, the timing controller 10 may control the power supply unit 40 (FIG. 1) and the like such that the timing controller 10 decreases the reference voltage by a predetermined level (inverse proportion) in correspondence with the increase of the operating point voltage, when it is determined that the temperature is increased.

In an embodiment, a temperature, and a voltage value of the reference voltage Vref corresponding to the temperature may be stored in the memory 12 and the like in a form of the look-up table (LUT). The timing controller 10 may determine the temperature based on the sensing data Vsen, and may select a voltage value of the reference voltage Vref corresponding to the temperature from the look-up table. The timing controller 10 may apply a power supply control signal PCS (FIG. 1) and the like to the power supply unit 40 such that the power supply unit 40 outputs the reference voltage Vref having the selected voltage value.

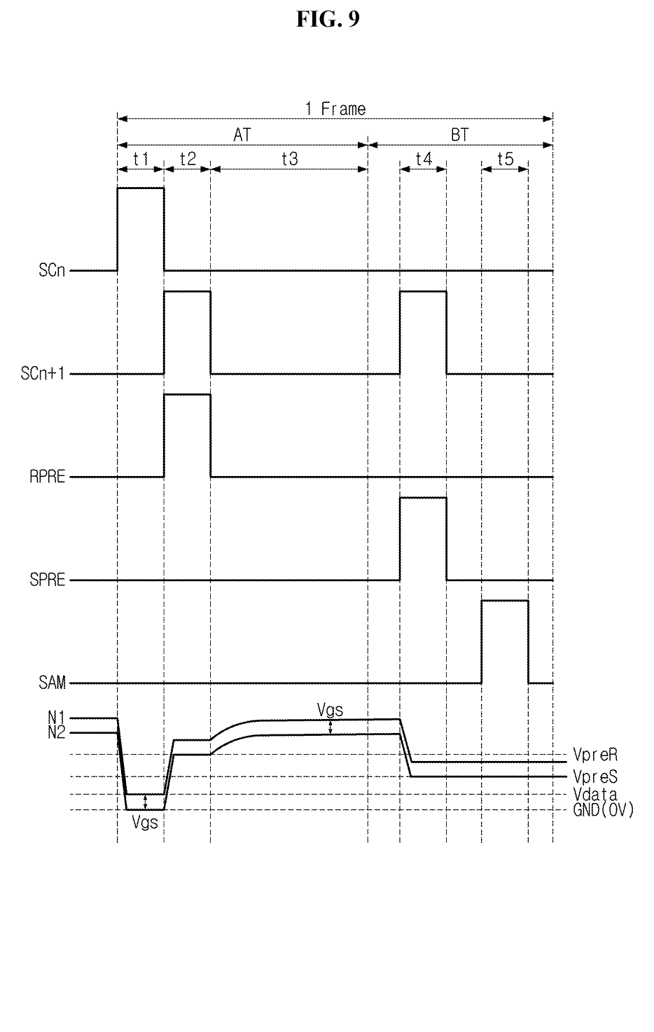

FIG. 9 is a schematic diagram illustrating a method for operating the pixel illustrated in FIG. 7 according to an embodiment.

Referring to FIGS. 7 and 9 together, one frame may include an active period AT configured to program the data voltage Vdata into the pixel PXn, and make the pixel PXn emit according to the programmed data voltage Vdata, and a blank period BT configured to sense an electric characteristic of the pixel PXn and perform compensation according to the sensing result.

The active period AT may include a programming period t1, a boosting period t2, and a light emitting period t3. In the active period AT, the reference voltage switch for displaying RPRE may be turned on and the reference voltage for displaying VpreR may be applied as the reference voltage Vref to the pixel PXn. The method in the active period AT is the same as what is described referring to FIG. 6, and thus, detailed description will be omitted.

The blank period BT may include a sensing period t4 and a sampling period t5.

In the sensing period t4, at least one of the first scan signal SCn and the second scan signal SCn+b may be in a turn-on level. Although not illustrated, according to the embodiment, the data voltage for sensing Vdata may be applied to the first node N1, and/or as the reference voltage switch for sensing SPRE is turned on, the reference voltage for sensing VpreS may be applied as the reference voltage Vref to the second node N2. In order to sense the electric characteristic of the pixel PX, a voltage of the second node N2 may be saturated in a required state.

When the second node N2 gets into a voltage state which reflects the desired characteristic value of the circuit element, the sampling switch SAM may be turned on. In the sampling period t5, the sensing signal output to the readout line RVL through the sampling switch SAM which is turned on, for example, a voltage and/or a current, may be applied to the data driver 30. The ADC may convert a voltage of the readout line RVL connected thereto into the digital data, generate the sensing data Vsen, and deliver it to the timing controller 10.

The timing controller 10 may compensate the data voltage Vdata, or compensate the reference voltage Vref based on the sensing data Vsen. For example, the timing controller 10 may increase the reference voltage Vref by a predetermined voltage value when it is determined that the temperature of the pixel PXn is increased based on the sensing data Vsen. The varied reference voltage Vref may be applied as the reference voltage for displaying VpreR to the pixel PXn in the active period AT of the next frame.

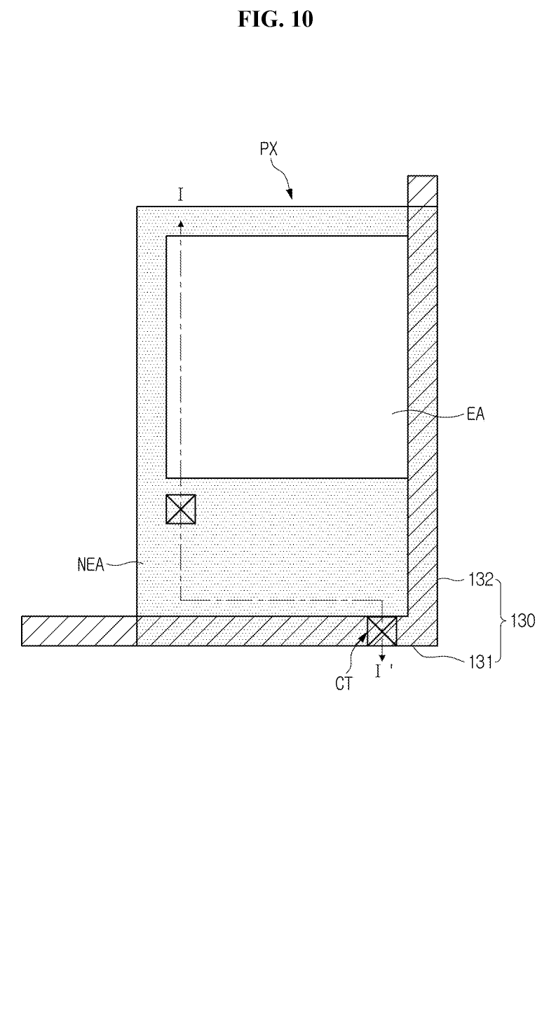

FIG. 10 is a schematic plan view of one region of the display device according to an embodiment.

Referring to FIG. 10, the plurality of pixels PX including an emitting region EA and a non-emission region NEA around the emitting region EA may be disposed on the display panel 50 according to an embodiment.

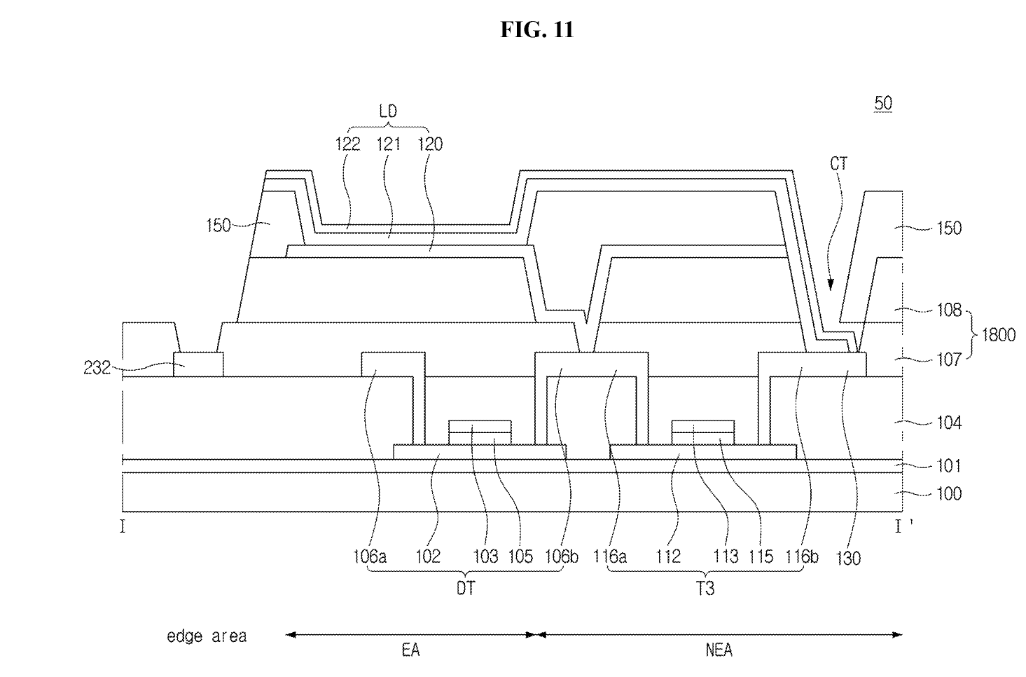

Such a pixel PX may include an auxiliary electrode 130 provided in the non-emission region NEA and configured to electrically contact a cathode electrode 122 (FIG. 11) and the low potential driving voltage ELVSS (FIG. 1) to each other. The auxiliary electrode 130 may be formed on the same layer and formed of the same material as the data line DL (FIG. 1), for example, and may be electrically connected to a cathode electrode 122 by having a contact portion for contacting the cathode electrode 122.

The auxiliary electrode 130 may be patterned together on the same layer as the data line DL, in particular, on the same layer as an electrode forming the thin film transistor, and may be formed as a single layer or a multi-layer formed of copper (Cu), aluminum (Al), molybdenum (Mo), titanium (Ti), or an alloy thereof, but is not limited thereto.

The auxiliary electrode 130 may be a line configured to receive the ground voltage or the low potential driving voltage as illustrated, and may include a first line 131 and a second line 132 extending perpendicularly to the first line 131 in general, but is not limited thereto. For example, the auxiliary electrode 130 may be configured of only one among the first line 131 and the second line 132.

FIG. 11 is a schematic cross-sectional view illustrating a stacked shape of the display device according to an embodiment. In more detail, FIG. 11 illustrates one region of a cross-section taken along I-I’ in FIG. 10.

Referring to FIG. 11, the display panel 50 may include a substrate 100, a circuit element layer and a light emission element layer disposed on the substrate 100. The circuit element layer may include one or more thin film transistor DT and T3, and a storage capacitor Cst, and the light emission element layer may include the light emitting element LD.

The substrate 100 supports various components of the display panel 50. The substrate 100 may be formed of a transparent insulating material, for example, glass, plastic, and the like. When the substrate 100 is formed of plastic, it may be referred to as a plastic film or a plastic substrate.

For example, the substrate 100 may be in a film form which includes one among polyimide polymer, polyester polymer, silicon polymer, acrylic polymer, polyolefin polymer, and a copolymer thereof, but the embodiments of the present disclosure are not limited thereto.

Also, when the substrate 100 is formed of plastic, the substrate 100 may be formed in a dual structure. For example, the substrate 100 may have a dual structure having an adhesive layer between a first polyimide layer and a second polyimide layer. For example, the substrate 100 may have a structure which includes an inter-layer insulating layer formed of an inorganic insulating material and interposed between the first polyimide layer and the second polyimide layer.

When the substrate 100 is formed of glass, the substrate 100 may be referred to as a glass substrate. For example, the glass substrate may further include a shielding metal (not illustrated) below the thin film transistors DT and T3, and may serve to protect the device from external light or signal interference.

On the substrate 100, a buffer layer 101 may be disposed. The buffer layer 101 may delay dispersion of moisture and/or oxygen which may permeate the substrate 100. The buffer layer 101 may include an inorganic matter, an organic matter, or organic/inorganic composites such as oxides and nitrides, and may be formed in a single layer or multi-layer structure. For example, the buffer layer 101 may have a structure of three or more layers consisting of silicon oxide, silicon nitride, and silicon oxide.

The thin film transistors DT and T3 for driving the light emitting element LD may be disposed on the substrate 100. In FIG. 11, the driving transistor DT and the third transistor T3 are illustrated as part of various transistors which may be included in the display device 1 (FIG. 1) for convenience of description.

In addition, an example in which the thin film transistors DT and T3 have a coplanar structure is described below, however, the thin film transistors DT and T3 may be implemented in various structures such as a staggered structure and the like.

The driving transistor DT may include a semiconductor layer 102, a gate electrode 103, and source and drain electrodes 106a and 106b, which are disposed on the buffer layer 101.

The semiconductor layer 102 may be formed of polysilicon p-Si, and in this case, a certain region may be doped with impurities. In addition, the semiconductor layer 102 may be formed of amorphous silicon a-Si, or various organic semiconductor materials such as pentacene. The semiconductor layer 102 may be formed of an oxide. The material configuring the semiconductor layer 102 is not limited to the embodiments described above. The semiconductor layer 102 may be referred to as an active layer.

In the semiconductor layer 102, a channel may be formed when the driving transistor DT is driven. The semiconductor layer 102 may include a channel region, a source region, and a drain region. The channel region may be disposed to overlap the gate electrode 103, and may be formed between the source region and the drain region. The source region and the drain region may be electrically connected to the source electrode and the drain electrode 106a and 106b through a contact hole, respectively.

The gate electrode 103 may be disposed to overlap the channel region of the semiconductor layer 102 on the semiconductor layer 102. The gate electrode 103 may be formed in a single layer or multi-layer structure made of various conductive materials, for example, magnesium (Mg), aluminum (Al), nickel (Ni), chrome (Cr), molybdenum (Mo), tungsten (W), gold (Au), or an alloy thereof, but embodiments of the present disclosure are not limited thereto.

The driving transistor DT may further include a gate insulating layer 105 disposed between the semiconductor layer 102 and the gate electrode 103 in a thickness direction. The gate insulating layer 105 may be a layer for insulating the semiconductor layer 102 and the gate electrode 103 from each other, and may be formed of an insulating material. For example, the gate insulating layer 105 may be formed in a single layer or multi-layer structure of silicon oxide SiOₓ, or silicon nitride SiNₓ, but is not limited thereto.

The source and drain electrodes 106a and 106b may be electrically connected to the source region and the drain region of the semiconductor layer 102, respectively, and may be spaced apart from each other. The source and drain electrodes 106a and 106b may be formed in a single layer or multi-layer structure formed of a conductive material, for example, copper (Cu), aluminum (Al), molybdenum (Mo), titanium (Ti), or an alloy thereof, but is not limited thereto.

At least one insulating layer may be interposed between the source and drain electrodes 106a and 106b and the gate electrode 103. For example, between the source and drain electrodes 106a and 106b and the gate electrode 103, an inter-layer insulating layer 104 may be interposed.

The third transistor T3 may include a semiconductor layer 112, a gate electrode 113, and source and drain electrodes 116a and 116b, which are disposed on the buffer layer 101.

The semiconductor layer 112 may be formed of an oxide semiconductor, and may be formed of an oxide semiconductor or various organic semiconductors such as amorphous silicon (a-Si), polycrystalline silicon (poly-Si), or pentacene, but is not limited thereto. The semiconductor layer 112 may be referred to as an active layer.

In the semiconductor layer 112, a channel may be formed when the third transistor T3 is driven. The semiconductor layer 112 may include a channel region, a source region, and a drain region. The channel region may be disposed to overlap the gate electrode 113 in a thickness direction, and may be formed between the source region and the drain region. The source region and the drain region may be electrically connected to the source electrode and the drain electrode 116a and 116b through a contact hole, respectively.

The gate electrode 113 may be disposed to overlap the channel region of the semiconductor layer 112 on the semiconductor layer 112. The gate electrode 113 may be formed in a single layer or multi-layer structure made of various conductive materials, for example, magnesium (Mg), aluminum (Al), nickel (Ni), chrome (Cr), molybdenum (Mo), tungsten (W), gold (Au), or an alloy thereof, but embodiments of the present disclosure are not limited thereto.

The third transistor T3 may further include a gate insulating layer 115 disposed between the semiconductor layer 112 and the gate electrode 113.

The source and drain electrodes 116a and 116b may be electrically connected to the source region and the drain region of the semiconductor layer 112, respectively, and may be spaced apart from each other. The source and drain electrodes 116a and 116b may be formed in a single layer or multi-layer structure formed of a conductive material, for example, copper (Cu), aluminum (Al), molybdenum (Mo), titanium (Ti), or an alloy thereof, but is not limited thereto.

At least one insulating layer may be interposed between the source and drain electrodes 116a and 116b and the gate electrode 113. For example, between the source and drain electrodes 116a and 116b and the gate electrode 113, the inter-layer insulating layer 104 may be interposed.

The insulating layers 104 and 105 may be formed in a single layer or multi-layer structure of silicon oxide SiOₓ, or silicon nitride SiNₓ.

In the illustrated embodiment, the driving transistor DT may be a driving transistor DT, and may be electrically connected to an anode electrode 120 of the light emitting element LD which will be described below. For example, a drain electrode 106b of the driving transistor DT may be electrically connected to the anode electrode 120 of the light emitting element LD through a contact hole.

In addition, the third transistor T3 may be a third transistor T3, and may be electrically connected to the cathode electrode 122 of the light emitting element LD which will be described below. For example, a drain electrode 116b of the third transistor T3 may be electrically connected to the cathode electrode 122 of the light emitting element LD through a contact hole.

In such an embodiment, the driving transistor DT and the third transistor T3 may be electrically connected to each other through the second node N2. At this instance, the drain electrode 106b of the driving transistor DT and the source electrode 116a of the third transistor T3 may be formed as one pattern.

In an outside region of the substrate 100, a pad electrode 232 may be further formed on the same layer as the source and drain electrodes 106a, 106b, 116a and 116b. The pad electrode 232 may not be covered by an inter-layer insulating stack 1800 and a bank 150 which will be described below, and expose part of its upper surface. Such a pad electrode 232 may be bonded to an FPC film and the like through the exposed region to receive an electric signal.

The inter-layer insulating stack 1800 may be formed between the thin film transistors DT and T3 and the light emitting element LD. The inter-layer insulating stack 1800 may be formed as a stack consisting of a protection film 107 which is an inorganic insulating layer and an overcoat layer 108 which is an organic insulating film that are stacked sequentially in a sequence from a side close to the substrate 100.

For example, the protection film 107 may be an oxide film, a nitride film, or an oxide nitride film, and may be deposited in one layer or in multiple layers of the aforementioned films. The overcoat layer 108 may be formed of an organic material to the thickness required for the flattening of convex and concave portions on the surface thereof, and may be formed of an organic film, such as, for example, a photo acryl film.

The light emitting element LD may be formed on the inter-layer insulating stack 1800. The light emitting element LD may have a structure in which the anode electrode 120, an emission layer 121, and the cathode electrode 122 are stacked.

The light emitting element LD may be a top emission type, a bottom emission type, or a dual emission type. When the light emitting element LD is the top emission type, the anode electrode 120 may be formed as an opaque or translucent electrode which reflects light, and the cathode electrode 122 may be formed as a transparent electrode which allows light to penetrate.

On contrary, when the light emitting element LD is the bottom emission type, the anode electrode 120 may be formed as a transparent electrode, and the cathode electrode 122 may be formed as an opaque or translucent electrode. Hereinafter, an example in which the light emitting element LD is the top emission type will be described.

The anode electrode 120 may include a metal material having a high reflectance such as a stacked structure (Ti/Al/Ti) of aluminum (Al) and titanium (Ti), a stacked structure (ITO/Al/ITO) of aluminum (Al) and ITO (Indium Tin Oxide), or an APC alloy, and may be formed of a single layer or a multi-layer, but embodiments of the present disclosure are not limited thereto. The anode electrode 210 may be electrically connected to the driving transistor DT through a contact hole.

A bank 150 may be formed on the anode electrode 120 and partially on the emission layer 121. The bank 150 may be disposed to cover one region of the anode electrode 120, for example, an edge of the anode electrode 120, and a remaining other region, for example, a center region thereof. The bank 150 may be formed to be wide on the substrate 100. An exposed region of the anode electrode 120 not covered by the bank 150 may be defined as an emission region EA and a region around the emission region may be defined as a non-emission region NEA.

The bank 150 may be formed of an opaque material to prevent an optical interference between adjacent pixels. For example, the bank 150 may include a black-based material, and may include a light shielding material formed of at least one among, for example, a color pigment (a black pigment), a black dye, organic black, and carbon (black bank).

Alternatively, the bank 150 may be formed of an organic material such as a benzocyclobutene resin, a polyimide resin, an acrylic resin, or photosensitive polymer, but the embodiments of the present disclosure are not limited. When the bank 150 is formed of the black-based material, the bank 150 may shield external light, and thus, may further improve luminance of the display device 1. At this instance, the bank 150 may serve to absorb light reflected from a lower side of the bank 150 among light incident from the outside.

In an embodiment, the bank 150 may be in a multi-layer structure. In such an embodiment, part of the multi-layer may include a black-based material, and another part may include a transparent-based material.

The emission layer 121 may be formed on the bank 150 and the exposed region of the anode electrode 120 which is not covered by the bank 150. When the light emitting element LD has the tandem structure, the emission layer 121 may have a structure in which a plurality of emission layers 121 are stacked in a thickness direction. Each of the emission layers 121 may form an emission unit, and organic layers such as the charge generation layer and the like may be interposed between the emission units.

The cathode electrode 122 may be formed on the emission layer 121. The cathode electrode 122 may be electrically connected to the low potential driving voltage line PL2 (FIG. 1) on an outermost side of the substrate 100. The cathode electrode 122 may include a transparent conductive material or metal such as ITO (Indium Tin Oxide) or IZO (Indium Zinc Oxide) through which the visible light is transmitted, but the embodiments of the present disclosure are not limited thereto.

In an embodiment, the cathode electrode 122 may be formed wide on the substrate 100. The cathode electrode 122 may be formed on an entire surface of the emission region EA and the non-emission region NEA. In such an embodiment, a voltage drop of the low potential driving voltage ELVSS which is applied to the cathode electrode 122 may occur.

In order to solve such a problem, the cathode electrode 122 may be electrically connected to the auxiliary electrode 130 in the non-emission region NEA provided in each pixel PXn, and may be electrically connected to the low potential driving voltage line PL2 through the auxiliary electrode 130. As the cathode electrode 122 is electrically connected to the low potential driving voltage line PL2 through the auxiliary electrode 130 having excellent conductivity, a resistance of the cathode electrode 122 may be reduced, and the voltage drop of the cathode electrode 122 which increases more toward a center from the outermost side of the substrate 100 may be prevented.

In an embodiment, the auxiliary electrode 130 may be formed on the same layer and formed of the same material as those of the source and drain electrodes 106a, 106b, 116a and 116b. In an embodiment, the auxiliary electrode 130 may be electrically connected to one among the transistors DT and T3. For example, the auxiliary electrode 130 may be electrically connected to the drain electrode 116b of the third transistor T3, and at this instance, the auxiliary electrode 130 and the drain electrode 116b may be formed as one pattern.

In the embodiment as above, the bank 150 and the inter-layer insulating stack 1800 may include a contact hole CT exposing the auxiliary electrode 130. In part of an inner side surface of the contact hole CT, a relatively recessed undercut may be formed by the pattern further recessed toward an inside. At this instance, the bank 150 may form the undercut which is positioned only on an upper side of the inter-layer insulating stack 1800, or formed on an upper side and part of a side surface thereof.

At least part of an opening region of the contact hole CT may overlap the auxiliary electrode 130 in a thickness direction. For example, the bank 150 may overlap the auxiliary electrode 130 on the side surface of the inter-layer insulating stack 1800.

In various other embodiments, the protruding pattern forming the undercut may be other material layer except the bank 150, for example, the overcoat layer 108 or the anode material layer and the like. However, the embodiments are not limited thereto.

On an upper surface of the auxiliary electrode 130 exposed by the contact hole CT, the emission layer 121 and the cathode electrode 122 may be stacked. The emission layer 121 and the cathode electrode 122 may extend from the emission region EA to the upper surface of the auxiliary electrode 130 formed in the non-emission region NEA.

The cathode electrode 122 having the lower linearity than the emission layer 121 is formed to be in direct contact with the auxiliary electrode 130 in one region of the exposed auxiliary electrode 130 on which the emission layer 121 is not formed. For example, the auxiliary electrode 130 and the cathode electrode 122 may contact each other below the undercut of the contact hole CT.

In more detail, the emission layer 121 on which deposition is conducted without an exposure mask may not be easily deposited to a lower side of the bank 150 which is protruded because of strong linearity and may not have a uniform thickness. In particular, the emission layer 121 may be formed uniformly on part of the upper surface of the emission region EA and the auxiliary electrode 130, but may not be formed on another upper surface of the auxiliary electrode 130 overlapping the undercut.

The cathode electrode 122 deposited in a sputtering manner may be uniformly formed on the upper surface of the auxiliary electrode 130 which is exposed below the undercut because metal particles are deposited while being diffuse reflected. Therefore, the cathode electrode 122 may be in direct contact with the auxiliary electrode 130 below the undercut.

In one or more embodiments, at least one encapsulation layer, a touch layer, a color filter layer and one or more optical functional layers may be further disposed on the light emitting element LD.

According to the above-described structure, the display device 1 according to an embodiment may reduce a resistance of the low potential driving voltage ELVSS applied to the cathode electrode 122, and at the same time, may improve luminance in the grayscale through proper control of the voltage of the second node N2.

The embodiments of the present disclosure have been described with reference to accompanying drawings. Those of ordinary skill in the art will recognize that the present disclosure may be embodied in other specific forms without departing from its spirit or essential characteristics. The described embodiments are to be considered in all respects only as illustrative and not restrictive. The scope of the present disclosure is therefore indicated by the appended claims rather than by the foregoing description. All changes which come within meaning and range of equivalency of the claims are to be embraced within the scope of the present disclosure.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a display panel having a plurality of pixels;
a gate driver configured to apply a scan signal to the plurality of pixels;
a data driver configured to apply a data voltage to the plurality of pixels through a data line;
a power supply unit configured to apply a driving voltage to the plurality of pixels; and
a timing controller configured to control an operation of the gate driver, the data driver, and the power supply unit,
wherein each of the plurality of pixels includes:
a light emitting element formed of a plurality of light emission units connected in series through a charge generation layer;
a driving transistor having a first electrode connected to a high potential driving voltage, a gate electrode connected to a first node, and a second electrode connected to an anode electrode of the light emitting element through a second node;
a first transistor connected between the data line and the first node and having a gate electrode configured to receive a first scan signal through a gate electrode of the first transistor;
a second transistor connected between a readout line to which a reference voltage is applied and the second node and having a gate electrode configured to receive a second scan signal;
a third transistor having a first electrode connected to a first voltage, a second electrode connected to the second node, and a gate electrode configured to receive the first scan signal; and
a storage capacitor connected between the first node and the second node.

2. The display device of claim 1,
wherein the reference voltage is set to a voltage value in a range from about 70% to about 95% of a turn-on voltage of the light emitting element.

3. The display device of claim 1, wherein the first voltage includes a ground voltage, and
wherein the first transistor and the third transistor are configured to apply a data voltage and the first voltage to the first node and the second node, respectively, in a first period in one frame in response to the first scan signal in a turn-on level, and
wherein the second transistor is configured to apply the reference voltage to the second node in response to the second scan signal in a turn-on level in the second period after the first period.

4. The display device of claim 3,
wherein the data voltage which is a voltage difference between the first node and the second node is programmed into each of the plurality of pixels in the first period,
wherein a voltage of the second node and the first node coupled to the second node is boosted in response to the reference voltage in the second period, and
wherein an electron and a hole previously charged are discharged in the light emitting element in response to the reference voltage.

5. The display device of claim 1,
wherein the reference voltage is configured to be varied on a frame basis in correspondence with a sensing result of electric characteristics of each of the plurality of pixels, and
wherein the reference voltage is configured to be varied in inverse proportion to a temperature of each of the plurality of pixels.

6. The display device of claim 1, further comprising:
a substrate including an emission region having the light emitting element and a non-emission region around the emission region;
the driving transistor and the third transistor formed on the substrate;
an auxiliary electrode formed on the substrate and disposed in the non-emission region;
an inter-layer insulating stack formed on the driving transistor, the third transistor, and the auxiliary electrode; and
the light emitting element disposed on the inter-layer insulating stack and including the anode electrode, an emission layer, and a cathode electrode,
wherein the cathode electrode is electrically connected to the auxiliary electrode through a contact hole penetrating the inter-layer insulating stack.

7. The display device of claim 6,
wherein the first electrode of the third transistor is electrically connected to the auxiliary electrode.

8. The display device of claim 6,
wherein in the contact hole, an undercut is formed in at least one region thereof,
wherein the cathode electrode and the auxiliary electrode are in contact with each other in a region overlapping the undercut in a thickness direction,
wherein the undercut is formed by recessing an inner side surface of the contact hole.

9. The display device of claim 6,
wherein the first electrode of the third transistor receives the first voltage or a low potential driving voltage through the auxiliary electrode.

10. The display device of claim 1,
wherein the light emitting element is a tandem light emitting element formed of a multiple-stack including at least three light emission units.

11. A method for operating a display panel, the display panel having a plurality of pixels, a gate driver configured to apply a scan signal to the plurality of pixels, a data driver configured to apply a data voltage to the plurality of pixels through a data line, a power supply unit configured to apply a driving voltage to the plurality of pixels, and a timing controller configured to control an operation of the gate driver, the data driver and the power supply unit, wherein each of the plurality of pixels includes: a light emitting element formed of a plurality of light emission units; a driving transistor having a first electrode connected to a high potential driving voltage, a gate electrode connected to a first node, and a second electrode connected to an anode electrode of the light emitting element through a second node; a first transistor connected between the data line and the first node and having a gate electrode configured to receive a first scan signal; a second transistor connected between a readout line to which a reference voltage is applied and the second node and having a gate electrode configured to receive a second scan signal; a third transistor having a first electrode connected to a first voltage, a second electrode connected to the second node, and a gate electrode configured to receive the first scan signal; and a storage capacitor connected between the first node and the second node, the method comprising:
applying the first scan signal in a turn-on level and applying a data voltage to the data line in a first period in an active period in one frame;
converting the first scan signal into a turn-off level and applying the second scan signal in a turn-on level in a second period; and
applying the second scan signal in a turn-off level in the third period.

12. The method of claim 11, further comprising:
applying the second scan signal in a turn-on level and applying a reference voltage for sensing to the second node in a fourth period in a blank period after an active period;
obtaining sensing data from an electric signal output through the readout line in a fifth period; and
varying the reference voltage based on the obtained sensing data.

13. The method of claim 12, wherein the varying of the reference voltage includes:
determining a temperature of each of the plurality of pixels based on the obtained sensing data;
selecting a voltage value corresponding to the determined temperature from a prestored look-up table; and
varying the reference voltage to the selected voltage value.

14. The method of claim 11,
wherein the reference voltage is set to be a voltage value in a range from about 70% to about 95% of a turn-on voltage of the light emitting element, and
wherein the turn-on voltage of the light emitting element increases in correspondence with a quantity of the light emission units.

15. A pixel, comprising:
a substrate including an emission region and a non-emission region around the emission region;
at least one thin film transistor formed on the substrate;
an auxiliary electrode formed on the substrate and disposed in the non-emission region;
an inter-layer insulating stack formed on the at least one thin film transistor and the auxiliary electrode; and
a light emitting element formed on the inter-layer insulating stack, disposed in the emission region, and having an anode electrode, a plurality of light emission units, a charge generation layer interposed between the plurality of light emission units, and a cathode electrode which are stacked in a thickness direction,
wherein the at least one thin film transistor includes:
a driving transistor including a first electrode connected to a high potential driving voltage, a gate electrode connected to a first node and a second electrode connected to the anode electrode through a second node; and
a switching transistor including a first electrode connected to a first voltage and a second electrode connected to the second node, and
wherein the cathode electrode is electrically connected to the auxiliary electrode through a contact hole penetrating the inter-layer insulating stack.

17. The pixel of claim 15,
wherein the first electrode of the switching transistor is electrically connected to the auxiliary electrode.

18. The pixel of claim 15,
wherein in the contact hole, an undercut is formed in at least one region,
wherein the cathode electrode and the auxiliary electrode are in contact with each other in a region overlapping the undercut, and
wherein the undercut is formed by recessing an inner side surface of the contact hole.

19. The pixel of claim 15,
wherein the light emitting element is a tandem light emitting element formed of a multiple-stack including at least three light emission units.

20. The pixel of claim 15,
wherein the at least one thin film transistor further includes a sensing transistor connected between a reference voltage and the second node, and
wherein the reference voltage is set to be a voltage value in a range from about 70% to about 95% of a turn-on voltage of the light emitting element.
